(19) United States
(12) Patent Application Publication
(10) Pub. No.: US 2014/0191386 A1
(43) Pub. Date: Jul. 10, 2014

(54) SEMICONDUCTOR PACKAGE AND FABRICATION METHOD THEREOF

(71) Applicant: Siliconware Precision Industries Co., Ltd., Taichung (TW)

(72) Inventors: Mei-Chin Lee, Taichung Hsien (TW); Wang-Ting Chen, Taichung Hsien (TW); Chi-Tung Yeh, Taichung Hsien (TW); Chun-Tang Lin, Taichung Hsien (TW); Yi-Che Lai, Taichung Hsien (TW)

(73) Assignee: SILICONWARE PRECISION INDUSTRIES CO., LTD., Taichung (TW)

(21) Appl. No.: 13/894,716

(22) Filed: May 15, 2013

(30) Foreign Application Priority Data
Jan. 4, 2013 (TW) 102100201

(51) Int. Cl. H01L 21/48; H01L 23/373

(52) U.S. Cl. CPC H01L 21/4882; H01L 23/3738
USPC 257/712; 438/113

(57) ABSTRACT

A semiconductor package is provided. The semiconductor package includes a substrate; a semiconductor element having opposite active and inactive surfaces and disposed on the substrate via the active surface thereof, wherein the inactive surface of the semiconductor element is roughened; a thermally conductive layer bonded to the inactive surface of the semiconductor element; and a heat sink disposed on the thermally conductive layer. The roughened inactive surface facilitates the bonding between the semiconductor element and the thermally conductive layer so as to eliminate the need to perform a gold coating process and the use of a flux and consequently reduce the formation of voids in the thermally conductive layer.

### BACKGROUND OF THE INVENTION

1. Field of the Invention

The present invention relates to semiconductor packages and fabrication methods thereof, and more particularly, to a semiconductor package and a fabrication method thereof for simplifying the fabrication process and improving the product yield.

2. Description of Related Art

Nowadays, semiconductor chips with increased integration and higher circuit density generate more and more heat, which must be dissipated effectively so as not to adversely affect the product reliability. Generally, a heat sink made of metal is attached to a back side of a chip through a thermal adhesive so as to facilitate heat dissipation. However, the use of the conventional thermal adhesive usually results in a low heat dissipation speed and cannot meet the heat dissipation requirement of the chip. In view of the drawback, a thermal interface material (TIM) has been developed.

A TIM layer is made of a thermally conductive material with a low melting point such as a solder material and disposed between the back side of the chip and the heat sink. In addition, a gold layer is coated on the back side of the chip to strengthen the bonding between the TIM layer and the chip, and a flux is applied to facilitate the bonding of the TIM layer to the gold layer.

FIGS. 1A and 1B are schematic cross-sectional views of a conventional semiconductor package 1. Referring to FIGS. 1A and 1B, a semiconductor element 11 is disposed on a substrate 10 via an active surface 11a thereof. A gold layer 110 is formed on an inactive surface 11b of the semiconductor element 11 by a gold coating process, and a solder layer 12a and a flux 12b are formed on the gold layer 110 and reflowed to attach a heat sink 13 to the gold layer 110. Therein, the solder material 12a and the flux 12b serve as a TIM layer 12.

Referring to FIG. 1B, the solder layer 12a and the flux 12b are shown as two layers for illustrative purposes. In practice, the solder layer 12a and the flux 12b are mixed into one layer.

In operation, heat generated by the semiconductor element 11 is conducted to the heat sink 13 through the inactive surface 11b, the gold layer 110 and the TIM layer 12 so as to be dissipated out of the semiconductor package 1.

However, the gold coating process easily causes pollution. Further, the gold coating process and the use of the flux complicate the fabrication process and increase the fabrication cost.

Further, as the flux 12b volatilizes when exposed to heat during the reflow process of the solder layer 12a, for example, voids v are formed in the TIM layer 12 and occupy about 40% of the volume of the TIM layer 12, thus reducing the thermal conductive area and decreasing the product yield.

Therefore, there is a need to provide a semiconductor package and a fabrication method thereof so as to overcome the above-described drawbacks.

### SUMMARY OF THE INVENTION

In view of the above-described drawbacks, the present invention provides a semiconductor package, which comprises: a substrate; a semiconductor element having opposite active and inactive surfaces and disposed on the substrate via the active surface thereof, wherein the inactive surface of the semiconductor element is a roughened surface; a thermally conductive layer bonded to the inactive surface of the semiconductor element; and a heat sink disposed on the thermally conductive layer.

The present invention further provides a fabrication method of a semiconductor package, which comprises the steps of: providing a substrate and disposing a semiconductor element on the substrate, wherein the semiconductor element has opposite active and inactive surfaces and is disposed on the substrate via the active surface thereof, and the inactive surface of the semiconductor element is a roughened surface; and disposing a heat sink on the inactive surface of the semiconductor element via a thermally conductive layer.

In an embodiment, the step of disposing the semiconductor element on the substrate comprises: providing a semiconductor substrate having a plurality of semiconductor elements; cutting the semiconductor substrate to separate the semiconductor elements from each other; disposing at least one of the semiconductor elements on the substrate; and performing a surface process to an inactive surface of the semiconductor element to form a roughened surface.

In another embodiment, the step of disposing the semiconductor element on the substrate comprises: providing a semiconductor substrate having a plurality of semiconductor elements; performing a surface process to an inactive surface of the semiconductor substrate to form a roughened surface; cutting the semiconductor substrate to separate the semiconductor elements from each other; and disposing at least one of the semiconductor elements on the substrate.

In an embodiment, the inactive surface of the semiconductor element is roughened through a surface process by using plasma.

In an embodiment, the step of disposing the heat sink on the inactive surface of the semiconductor element via the thermally conductive layer comprises: forming the thermally conductive layer on the inactive surface of the semiconductor element; and disposing the heat sink on the thermally conductive layer.

In another embodiment, disposing the heat sink on the inactive surface of the semiconductor element via the thermally conductive layer comprises: forming the thermally conductive layer on the heat sink; and disposing the heat sink on the inactive surface of the semiconductor element with the thermally conductive layer bonded to the inactive surface of the semiconductor element.

In an embodiment, the thermally conductive layer is laminated on the inactive surface of the semiconductor element.

In an embodiment, the method further comprises reflowing the thermally conductive layer.

In an embodiment, the active surface of the semiconductor element has a plurality of electrode pads electrically connected to the substrate.

In an embodiment, the thermally conductive layer is made of a thermally conductive material with a low melting point such as a solder material. In an embodiment, the thermally conductive layer comprises indium (In), which accounts for 99.99% of the weight of the thermally conductive layer. In an embodiment, the thermally conductive layer has a melting point lower than 170° C.

In an embodiment, the substrate has a stiffener disposed thereon for supporting the heat sink.

According to the present invention, the inactive surface of the semiconductor element is roughened to strengthen the bonding between the semiconductor element and the thermally conductive layer, thereby eliminating the need to perform a gold coating process and the use of a flux. Therefore, the present invention simplifies the fabrication process, reduces the fabrication cost and greatly reduces the ratio of voids in the thermally conductive layer so as to increase the thermally conductive area and improve the product yield.

### BRIEF DESCRIPTION OF DRAWINGS

FIG. 1A is a schematic cross-sectional view of a conventional semiconductor package;

FIG. 1B is a partially enlarged view of FIG. 1A;

FIGS. 2A to 2D are schematic cross-sectional views showing a fabrication method of a semiconductor package according to a first embodiment of the present invention; and

FIGS. 3A to 3C are schematic cross-sectional views showing a fabrication method of a semiconductor package according to a second embodiment of the present invention.

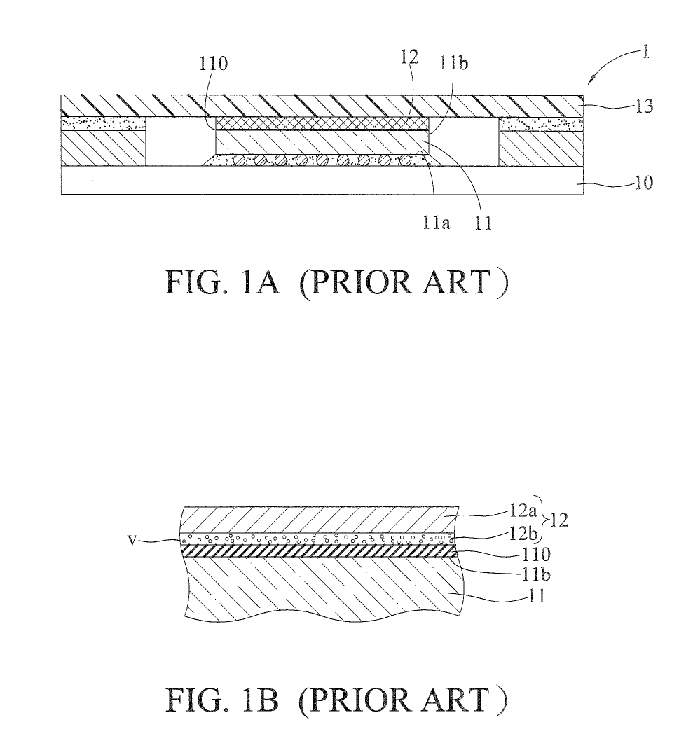

### DETAILED DESCRIPTION OF PREFERRED EMBODIMENTS

The following illustrative embodiments are provided to illustrate the disclosure of the present invention, these and other advantages and effects can be apparent to those in the art after reading this specification.

It should be noted that all the drawings are not intended to limit the present invention. Various modifications and variations can be made without departing from the spirit of the present invention. Further, terms such as “upper”, “first”, “second” etc. are merely for illustrative purposes and should not be construed to limit the scope of the present invention.

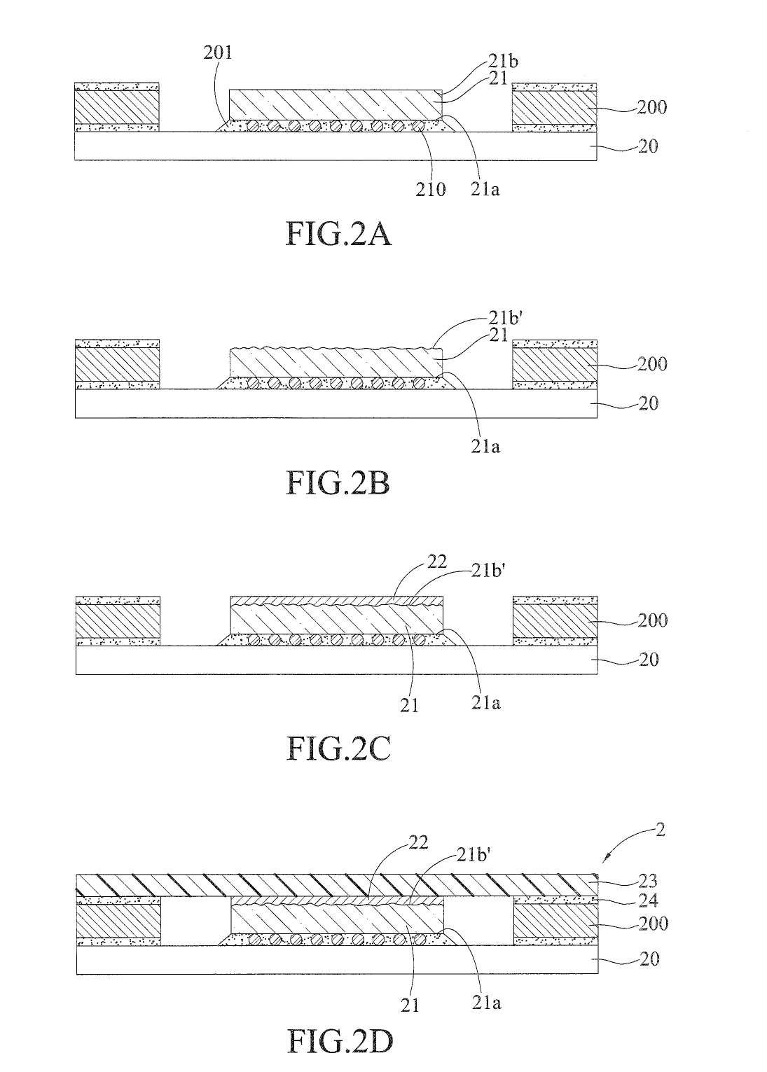

FIGS. 2A to 2D are schematic cross-sectional views showing a fabrication method of a semiconductor package 2 according to a first embodiment of the present invention.

Referring to FIG. 2A, a semiconductor substrate (not shown) having a plurality of semiconductor elements 21 is provided and cut to separate the semiconductor elements 21 from each other. Each of the semiconductor elements 21 has an active surface 21a with a plurality of electrode pads (not shown) thereon and an inactive surface 21b opposing to the active surface 21a.

Then, one of the semiconductor elements 21 is disposed on a substrate 20 via the active surface 21a and the electrode pads of the active surface 21a are electrically connected to the substrate 20 through a plurality of conductive bumps 210.

In the present embodiment, the substrate 20 can be a multi-layer ceramic substrate, an organic substrate such as a core layer made of BT (bismaleimide triazine) resin or FR4 resin, or a silicon-containing substrate such as an interposer having TSVs (through silicon vias).

The semiconductor element 21 is a chip. At least a stiffener 200 is disposed around an outer periphery of the substrate 20. The stiffener 200 can have a ring shape or include a plurality of posts. An underfill 201 is formed between the semiconductor element 21 and the substrate 20 for encapsulating the conductive bumps 210. The conductive bumps 210 can be solder bumps.

Referring to FIG. 2B, a surface treatment process is performed to the inactive surface 21b of the semiconductor element 21 so as to form a roughened surface 21b′. In the present embodiment, the surface process is performed by using plasma so as to form the roughened surface and remove a surface oxidized layer on the semiconductor element 21.

Referring to FIG. 2C, a thermally conductive layer 22 is directly bonded to the roughened inactive surface 21b′ of the semiconductor element 21.

In the present embodiment, the thermally conductive layer 22 is a solder layer. In another embodiment, the thermally conductive layer 22 contains indium (In) which is 99.99% by weight of the thermally conductive layer 22. Further, the thermally conductive layer 22 has a melting point lower than 170° C.

Referring to FIG. 2D, the thermally conductive layer 22 is reflowed and a heat sink 23 is disposed on the thermally conductive layer 22. Therein, the thermally conductive layer 22 serves as a TIM layer.

In the present embodiment, the reflow process can be performed in a vacuum reflow oven and the reflow temperature is lower than 200° C.

Further, the heat sink 23 is attached to the stiffener 200 through an electrically insulating material 24. The stiffener 200 helps to support the heat sink 23 so as for the heat sink 23 to be securely fixed on the thermally conductive layer 22.

In an embodiment, the thermally conductive layer 22 is formed on the heat sink 23 first and then reflowed so as for the heat sink 23 to be disposed on the inactive surface 21b′ of the semiconductor element 21 via the thermally conductive layer 22.

According to the present invention, the inactive surface 21b′ of the semiconductor element 21 is roughened to increase the area of bonding between the semiconductor element 21 and the thermally conductive layer 22, thereby eliminating the need to perform a gold coating process on the inactive surface 21b′, the use of a flux and fabrication of other plating layers.

Therefore, the present invention simplifies the fabrication process and reduces the fabrication cost. Further, when the thermally conductive layer 22 is reflowed, no flux volatilization will be occurred in the fabricating process. As such, voids formed in the thermally conductive layer 22 will be reduced and occupy at most 5% of the volume of the thermally conductive layer 22, thus increasing the thermally conductive area and effectively improving the product yield.

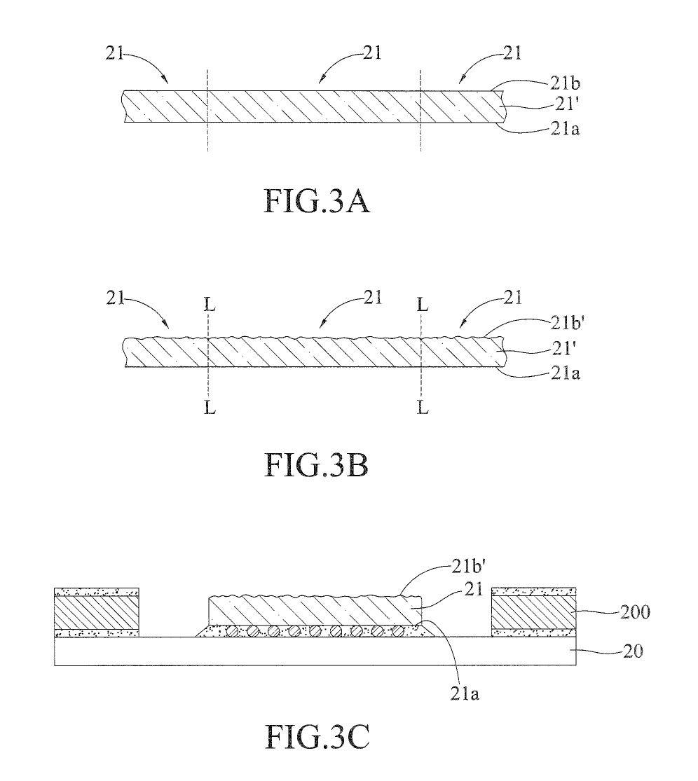

FIGS. 3A to 3C are schematic cross-sectional views showing a fabrication method of a semiconductor package 2 according to a second embodiment of the present invention. The present embodiment differs from the first embodiment in the process of the semiconductor element 21.

Referring to FIG. 3A, a semiconductor substrate 21′ is provided, which has a plurality of semiconductor elements 21 each having an active surface 21a and an inactive surface 21b opposite to the active surface 21a.

Referring to FIG. 3B, a surface treatment process is performed to the inactive surfaces 21b of the semiconductor elements 21 so as to form roughened surfaces 21b′.

Referring to FIG. 3C, the semiconductor substrate 21′ is cut along a cutting path L of FIG. 3B so as to separate the semiconductor elements 21 from each other. As such, each of the semiconductor elements 21 has a roughened surface. Then, one of the semiconductor elements 21 is disposed on the substrate 20 via the active surface 21a and the processes as shown in FIGS. 2C to 2D are performed subsequently.

The present invention further provides a semiconductor package 2, which has: a substrate 20, a semiconductor element 21 disposed on the substrate 20, a thermally conductive layer 22 bonded to the semiconductor element 21 and a heat sink 23 disposed on the thermally conductive layer 22.

The semiconductor element 21 has an active surface 21a with a plurality of electrode pads (not shown) and a roughened inactive surface 21b′ opposing to the active surface 21a. The semiconductor element 21 is disposed on the substrate 20 via the active surface 21a thereof and the electrode pads of the active surface 21a are electrically connected to the substrate 20 through a plurality of conductive bumps 210.

The thermally conductive layer 22 is bonded to the inactive surface 21b′ of the semiconductor element 21. The thermally conductive layer 22 is a solder layer and has a melting point lower than 170° C. Further, the thermally conductive layer 22 contains indium (In), which accounts for 99.99% of the weight of the thermally conductive layer 22.

The semiconductor package 2 further has at least a stiffener 200 disposed on the substrate 20 for supporting the heat sink 23.

According to the present invention, the inactive surface of the semiconductor element is roughened so as for the semiconductor element to be securely bonded to the thermally conductive layer, thereby eliminating the need to perform a gold coating process and the use of a flux. Therefore, the present invention simplifies the fabrication process, reduces the fabrication cost and greatly reduces the ratio of voids in the TIM layer, i.e., the thermally conductive layer, so as to increase the thermally conductive area and improve the product yield.

The above-described descriptions of the detailed embodiments are only to illustrate the preferred implementation according to the present invention, and it is not to limit the scope of the present invention. Accordingly, all modifications and variations completed by those with ordinary skill in the art should fall within the scope of present invention defined by the appended claims.

What is claimed is:

1. A semiconductor package, comprising:
a substrate;
a semiconductor element having an active surface and an inactive surface opposing to the active surface and disposed on the substrate via the active surface, wherein the inactive surface of the semiconductor element is roughened;
a thermally conductive layer bonded to the inactive surface of the semiconductor element; and
a heat sink disposed on the thermally conductive layer.

2. The package of claim 1, wherein the active surface of the semiconductor element has a plurality of electrode pads electrically connected to the substrate.

3. The package of claim 1, wherein the thermally conductive layer is made of a low melting point thermally conductive material.

4. The package of claim 3, wherein the thermally conductive layer is made of a solder material.

5. The package of claim 1, wherein the thermally conductive layer comprises indium (In).

6. The package of claim 1, wherein the thermally conductive layer comprises 99.99% of indium (In) by weight.

7. The package of claim 1, wherein the thermally conductive layer has a melting point lower than 170° C.

8. The package of claim 1, further comprising a stiffener disposed on the substrate for supporting the heat sink.

9. A fabrication method of a semiconductor package, comprising the steps of:
disposing a semiconductor element on a substrate, wherein the semiconductor element has opposite active and inactive surfaces and is disposed on the substrate via the active surface thereof, and the inactive surface of the semiconductor element is roughened; and
disposing a heat sink on the inactive surface of the semiconductor element via a thermally conductive layer.

10. The method of claim 9, wherein the step of disposing the semiconductor element on the substrate comprises:
providing a semiconductor substrate having a plurality of semiconductor elements;
cutting the semiconductor substrate to separate the semiconductor elements from each other;
disposing at least one of the semiconductor elements on the substrate; and
performing a surface treatment process to an inactive surface of the semiconductor element to form a roughened surface.

11. The method of claim 9, wherein the step of disposing the semiconductor element on the substrate comprises:
providing a semiconductor substrate having a plurality of semiconductor elements;
performing a surface treatment process to an inactive surface of the semiconductor substrate to form a roughened surface;
cutting the semiconductor substrate to separate the semiconductor elements with the roughened surface from each other; and
disposing at least one of the semiconductor elements on the substrate.

12. The method of claim 9, wherein the inactive surface of the semiconductor element is roughened through a surface process by using plasma.

13. The method of claim 9, wherein the step of disposing the heat sink on the inactive surface of the semiconductor element via the thermally conductive layer comprises:
forming the thermally conductive layer on the inactive surface of the semiconductor element; and
disposing the heat sink on the thermally conductive layer.

14. The method of claim 9, wherein the step of disposing the heat sink on the inactive surface of the semiconductor element via the thermally conductive layer comprises:
forming the thermally conductive layer on the heat sink; and
disposing the heat sink on the inactive surface of the semiconductor element with the thermally conductive layer bonded to the inactive surface of the semiconductor element.

15. The method of claim 9, wherein the thermally conductive layer is laminated on the inactive surface of the semiconductor element.

16. The method of claim 9, wherein the active surface of the semiconductor element has a plurality of electrode pads electrically connected to the substrate.

17. The method of claim 9, wherein the thermally conductive layer is made of a thermally conductive material having a low melting point.

18. The method of claim 17, wherein the thermally conductive layer is made of a solder material.

19. The method of claim 9, wherein the thermally conductive layer comprises indium (In)

20. The method of claim 9, wherein the thermally conductive layer comprises 99.99% of indium (In) by weight.

21. The method of claim 9, wherein the thermally conductive layer has a melting point lower than 170° C.

22. The method of claim 9, further comprising reflowing the thermally conductive layer.

23. The method of claim 9, wherein the substrate further has a stiffener disposed thereon for supporting the heat sink.
